(19) United States
(12) Patent Application Publication
(10) Pub. No.: US 2024/0043710 A1
(43) Pub. Date: Feb. 8, 2024

(54) Ultraviolet-Curable Conductive Ink

(71) Applicant: Apple Inc., Cupertino, CA (US)

(72) Inventors: Ken Hsuan Liao, San Jose, CA (US); Ying-Chih Wang, Sunnyvale, CA (US); Shu Yang, Sunnyvale, CA (US); Yu-Jen Fang, San Jose, CA (US); Po-Jui Chen, Cupertino, CA (US); Andrew H Moon, El Dorado Hills, CA (US); Sarah Trabia, San Jose, CA (US); Nathan K Gupta, Hillsborough, CA (US)

(21) Appl. No.: 17/972,379

(22) Filed: Oct. 24, 2022

Related U.S. Application Data
(60) Provisional application No. 63/395,296, filed on Aug. 4, 2022.

(51) Int. Cl. C09D 11/52; H05K 5/03; H01B 1/24; C09D 11/037; C09D 11/101

(52) U.S. Cl. CPC C09D 11/52; H05K 5/03; H01B 1/24; C09D 11/037; C09D 11/101

(57) ABSTRACT

A conductive ink may include an ultraviolet-curable resin and high-aspect-ratio conductors, such as nanowires or carbon nanotubes, dispersed in the ultraviolet-curable resin. The conductive ink may be fully curable at room temperature in under a minute with a curing depth of at least 100 microns, without heat, moisture, or a secondary curing step. The conductive ink may also have pigment and/or dyes within the ultraviolet-curable resin, and the conductive ink may be opaque at infrared wavelengths and transparent at ultraviolet wavelengths. The conductive ink may ground the cover glass of an electronic device display to a metal structure within the electronic device, such as a metal plate of the display, to prevent an accumulation of charge at the cover glass.

This application claims the benefit of provisional patent application No. 63/395,296, filed Aug. 4, 2022, which is hereby incorporated by reference herein in its entirety.

### BACKGROUND

This relates generally to ink, and more particularly, to conductive ink.

Conductive ink may be used in electronic devices or other contexts. In some cases, however, it may be difficult to cure the conductive ink.

### SUMMARY

A conductive ink may be ultraviolet-curable and include conductors dispersed in an ultraviolet-curable resin. The conductors may have high aspect ratios, and may be nanowires or carbon nanotubes, as examples. Because of the small size and dispersed nature of the conductors, ultraviolet light incident on the conductive ink may penetrate the entirety of the ultraviolet-curable resin. As a result, the conductive ink may be fully curable using ultraviolet light at room temperature without heat, moisture, or a secondary curing method. For example, the conductive ink may have a curing depth of at least 100 microns in a curing time of less than one minute.

The conductive ink may be incorporated into electronic devices, such as electronic devices with displays. For example, the conductive ink may ground a cover layer that overlaps an electronic device display to a metal structure, such as a metal plate of the display. This may prevent charge accumulation at the cover layer.

Colorants, such as pigments or dyes, may be included in the conductive ink. The conductive ink may be opaque at visible wavelengths, while remaining transparent at ultraviolet wavelengths. The conductive ink may be used both as a masking layer, due to its opacity at visible light, as well as a grounding layer, due to its conductivity, while remaining curable using ultraviolet light.

### BRIEF DESCRIPTION OF THE DRAWINGS

FIG. 1 is a schematic diagram of an illustrative electronic device having control circuitry and input-output devices in accordance with various embodiments.

FIG. 2 is a diagram of an illustrative electronic device having a display in accordance with various embodiments.

FIGS. 3A and 3B are side views of illustrative displays having conductive ink structures in accordance with various embodiments.

FIG. 4 is a side view of an illustrative ultraviolet-curable conductive ink having dispersed conductors with non-linear profiles in accordance with various embodiments.

FIG. 5 is a side view of an illustrative ultraviolet-curable conductive ink having dispersed conductors with linear profiles in accordance with various embodiments.

FIG. 6 is a graph of an illustrative relationship between optical density and wavelength for an ultraviolet-curable conductive ink in accordance with various embodiments.

FIG. 7 is a graph of an illustrative relationship between optical density and wavelength for an ultraviolet-curable conductive ink that includes a plurality of dyes in accordance with various embodiments.

FIG. 8 is a flowchart of illustrative steps in applying an ultraviolet-curable conductive ink to a desired surface and curing the ink in accordance with various embodiments.

### DETAILED DESCRIPTION

Electronic devices may be provided with inks, such as conductive inks. For example, electronic devices may include displays or other electronic components. These components may be grounded to other structures within the electronic device. To ground these components, a conductive ink may be used. In particular, an ultraviolet-curable conductive ink may ground structures within the device. The ultraviolet-curable ink may have a conductor dispersed within an ultraviolet-curable resin. The conductor may have a high aspect ratio to allow ultraviolet light to reach the entirety of the ultraviolet-curable resin during curing. As a result, the ultraviolet-curable ink may be fully curable using ultraviolet light, without a secondary curing process. As an example, the ultraviolet-curable ink may be curable at room temperature in less than one minute. Therefore, the manufacturing process of applying the ink to a desired surface and curing the ink may be simplified.

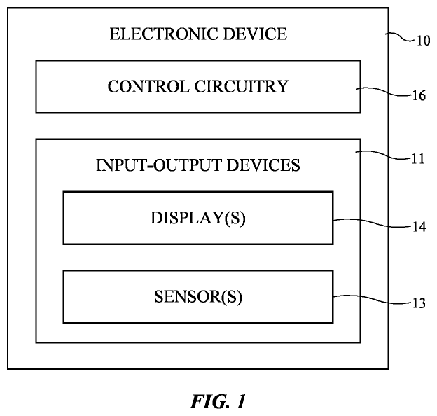

An illustrative electronic device of the type that may be provided with an ultraviolet-curable conductive ink is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, a device embedded in eyeglasses or other equipment worn on a user's head, or other wearable or miniature device, a display, a computer display that contains an embedded computer, a computer display that does not contain an embedded computer, a gaming device, a navigation device, a head-mounted device, an embedded system such as a system in which electronic equipment with a display is mounted in a kiosk or automobile, or other electronic equipment. Electronic device 10 may have the shape of a pair of eyeglasses (e.g., supporting frames), may form a housing having a helmet shape, or may have other configurations to help in mounting and securing the components of one or more displays on the head or near the eye of a user.

As shown in FIG. 1, electronic device 10 may include control circuitry 16 for supporting the operation of device 10. Control circuitry 16 may include storage such as hard disk drive storage, nonvolatile memory (e.g., flash memory or other electrically-programmable-read-only memory configured to form a solid-state drive), volatile memory (e.g., static or dynamic random-access memory), etc. Processing circuitry in control circuitry 16 may be used to control the operation of device 10. The processing circuitry may be based on one or more microprocessors, microcontrollers, digital signal processors, baseband processors, power management units, audio chips, application-specific integrated circuits, etc. Communications circuitry in control circuitry 16 may be used to communicate with external devices or equipment. The communications circuitry may include any number of antennas, baseband processors, etc. that allow for communicating with other devices.

Input-output circuitry in device 10 such as input-output devices 11 may be used to allow data to be supplied to device 10 (e.g., to be supplied to control circuitry 16) and to allow data to be provided from device 10 to external devices (e.g., to be provided from control circuitry 16 to external devices). Input-output devices 12 may include buttons, joysticks, scrolling wheels, touch pads, key pads, keyboards, microphones, speakers, tone generators, vibrators, cameras, sensors, light-emitting diodes and other status indicators, data ports, etc. A user can control the operation of device 10 by supplying commands through input resources of input-output devices 12 and may receive status information and other output from device 10 using the output resources of input-output devices 12.

Input-output devices 12 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements. A touch sensor for display 14 may be formed from electrodes formed on a common display substrate with the display pixels of display 14 or may be formed from a separate touch sensor panel that overlaps the pixels of display 14. If desired, display 14 may be insensitive to touch (i.e., the touch sensor may be omitted). Display 14 may be an organic light-emitting diode display, a display formed from an array of discrete light-emitting diodes (microLEDs) each formed from a crystalline semiconductor die, a liquid crystal display (LCD), or any other suitable type of display. This is, however, merely illustrative. Any suitable type of display may be used, if desired. In general, display 14 may have a rectangular shape (i.e., display 14 may have a rectangular footprint and a rectangular peripheral edge that runs around the rectangular footprint) or may have other suitable shapes. Display 14 may be planar or may have a curved profile.

Regardless of the display technology and profile of display 14, control circuitry 16 may be used to run software on device 10 such as operating system code and applications. During operation of device 10, the software running on control circuitry 16 may display images on display 14.

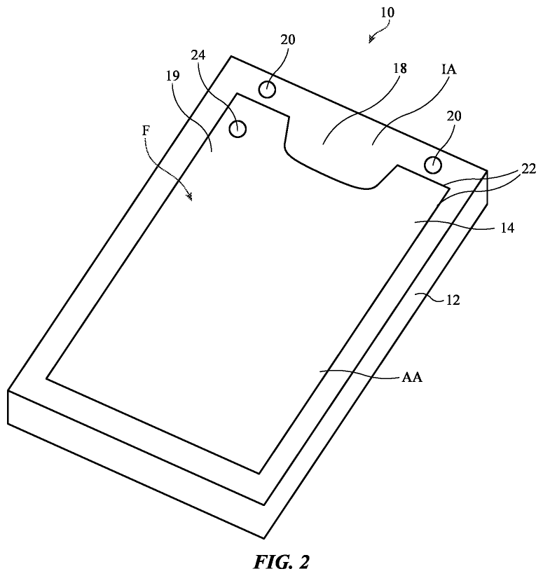

Input-output devices 12 may also include one or more sensors 13 such as force sensors (e.g., strain gauges, capacitive force sensors, resistive force sensors, etc.), audio sensors such as microphones, touch and/or proximity sensors such as capacitive sensors (e.g., a two-dimensional capacitive touch sensor associated with a display and/or a touch sensor that forms a button, trackpad, or other input device not associated with a display), and other sensors. In accordance with some embodiments, sensors 13 may include optical sensors such as optical sensors that emit and detect light (e.g., optical proximity sensors such as transreflective optical proximity structures), ultrasonic sensors, and/or other touch and/or proximity sensors, monochromatic and color ambient light sensors, image sensors (cameras), fingerprint sensors, temperature sensors, proximity sensors and other sensors for measuring three-dimensional non-contact gestures (“air gestures”), pressure sensors, sensors for detecting position, orientation, and/or motion (e.g., accelerometers, magnetic sensors such as compass sensors, gyroscopes, and/or inertial measurement units that contain some or all of these sensors), health sensors, radio-frequency sensors, depth sensors (e.g., structured light sensors and/or depth sensors based on stereo imaging devices), optical sensors such as self-mixing sensors and light detection and ranging (lidar) sensors that gather time-of-flight measurements, humidity sensors, moisture sensors, gaze tracking sensors, and/or other sensors. In some arrangements, device 10 may use sensors 13 and/or other input-output devices to gather user input (e.g., buttons may be used to gather button press input, touch sensors overlapping displays can be used for gathering user touch screen input, touch pads may be used in gathering touch input, microphones may be used for gathering audio input, accelerometers may be used in monitoring when a finger contacts an input surface and may therefore be used to gather finger press input, etc.). An example of device 10 is shown in FIG. 2.

As shown in FIG. 2, device 10 may be a cellular telephone or tablet computer. However, device 10 of FIG. 2 is merely illustrative, and device 10 may be any desired electronic device.

Device 10 may include housing 12, which may be formed from metal, glass, plastic, ceramic, and/or any other desired material. In some illustrative examples, housing 12 may have a glass rear face, a transparent cover layer (such as a glass layer) on the front face F, and metal sidewalls that extend from the glass rear face to front face F. In general, however, housing 12 may be formed from one or more desired materials.

Device 10 may include display 14. Display 14 may be an organic light-emitting diode (OLED) display, a display formed from an array of discrete light-emitting diodes (microLEDs) each formed from a crystalline semiconductor die, a liquid crystal display, or any other suitable type of display. Device configurations in which display 14 is an OLED display are sometimes described herein as an example. This is, however, merely illustrative. Any suitable type of display may be used, if desired. In general, display 14 may have a rectangular shape (i.e., display 14 may have a rectangular footprint and a rectangular peripheral edge that runs around the rectangular footprint) or may have other suitable shapes. Display 14 may be planar or may have a curved profile.

As shown in FIG. 2, display 14 may be visible from front face F. In some embodiments, a transparent cover layer, such as a glass layer or sapphire layer, may cover display 14 and form front face F. In general, display 14 may have any desired shape. Display 14 may extend across the entirety of front face F; may have one or more notches, such as notch 18; may have one or more openings, such as opening 19, in active area AA of display 14 (i.e., an active area in which pixels would otherwise be present—in other words, opening 19 may be surrounded by display pixels of display 14); and/or may have one or more openings, such as openings 20, in inactive area IA of display 14 (i.e., an inactive region that surrounds the active area). These notches and openings are merely illustrative. In general, display 14 may have any desired number of notches and/or openings.

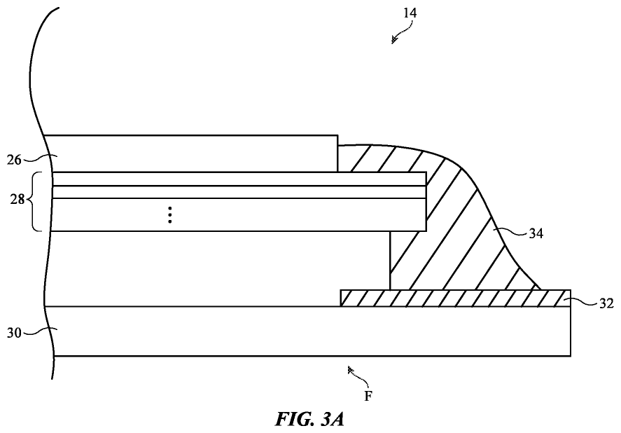

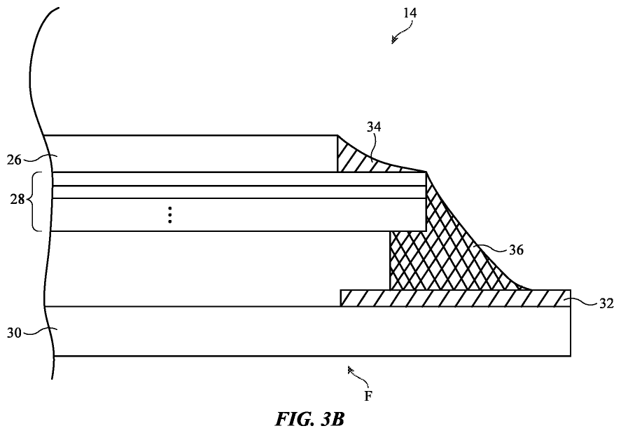

Portions of display 14 may abut openings in the display and/or the inactive area that surrounds the display. For example, active area AA of display 14 may be adjacent to inactive area IA at edges 22 (and entirely around the periphery of the active area, if desired). Alternatively or additionally, portions of display 14 may surround opening 19 at location 24. Portions of display 14 may be adjacent to notch 18 and/or openings 20 (e.g., inactive area IA of display 14 may be adjacent to openings 20). Within these areas (or other portions of display 14), it may be desirable to ground the transparent cover layer to a structure within device 10. For example, conductive ink may be used to ground the transparent cover layer to a metal structure in device 10 to reduce or eliminate charge accumulation at the transparent cover layer as the device 10 is used. Examples of this arrangement are shown in FIGS. 3A and 3B.

As shown in FIG. 3A, display 14 may include metal plate 26 and display layers 28. Depending on the display technology of display 14 (e.g., OLED display technology), display layers 28 may include layers such as an organic emissive layer, an anode layer, a cathode layer, a thin-film transistor layer, and/or other desired layers.

Display 14 may be covered by cover layer 30. Cover layer 30 may be a transparent (or substantially transparent cover layer) through which a user views images displayed by display 14. Cover layer 30 may be formed from glass, sapphire, or plastic, as examples. An outer surface of cover layer 30 may form front face F of device 10, while an inner surface of cover layer 30 may face display 14.

A masking layer, such as masking layer 32, may be coupled to portions of cover layer 32. For example, masking layer 32 may overlap the inactive area of display 14, may be present in notches in display 14, may surround openings in display 14, or may otherwise may be present on cover layer 30. Masking layer 32 may be an opaque masking layer, such as a black masking layer, or a masking layer with a different opacity and/or color. Moreover, masking layer 32 may be formed from ink, thin-film interference filter layers, and/or other desired layers. In some examples, masking layer 32 may be a black ink layer to hide underlying components from the view of a user of device 10.

To ensure that charge does not build up on cover layer 30 while device 10 is in use, it may be desirable to ground cover layer 30 to other structures within device 10. In some examples, conductive ink 34 may be used to ground cover layer 30 to metal plate 26 of display 14. As shown in FIG. 3A, for example, conductive ink 34 may ground masking layer 32 to metal plate 26. In this way, any charge that may otherwise build up on cover layer 30 may instead be grounded to metal plate 26, avoiding an accumulation of charge at cover layer 30.

Conductive ink 34 may be an ultraviolet-curable conductive ink. In particular, conductive ink 34 may be fully curable at room temperature using ultraviolet light in under one minute, under 30 seconds, under 10 seconds, or other desired curing time. In some examples, conductive ink 34 may have a curing depth of at least 50 microns, at least 100 microns, at least 150 microns, at least 200 microns, or other curing depth in under one minute. However, these curing times and depths are merely illustrative. In general, because conductive ink 34 is fully curable at room temperature using ultraviolet light in a short curing time, the manufacturing of display 14 (and therefore device 10) may be simplified and its speed may be increased.

Although FIG. 3A shows conductive ink 34 extending from metal plate 26 to masking layer 32 on cover layer 30, this is merely illustrative. In some embodiments, conductive ink 34 may be grounded directly to cover layer 30 (i.e., without masking layer 32 between conductive ink 34 and cover layer 30). Alternatively, conductive ink 34 may be grounded to a structure other than metal plate 26 within device 10, such as a metal frame or support structure. An alternative arrangement is shown in FIG. 3B.

As shown in FIG. 3B, conductive ink 34 may ground metal plate 26 to the edge of display layers 28. In particular, electronic device 10 may include an edge light blocking structure at the edge of display layers 28. The edge light blocking structure may be, for example, a metal layer. In this way, conductive ink 34 may ground metal plate 26 to the edge light blocking structure. In general, however, conductive ink 34 may ground metal plate 26 to any desired structure in device 10.

Because conductive ink 34 does not extend to cover layer 30, ink seal 36 may further be included. In particular, ink seal 36 may extend from masking layer 32 on cover layer 30 to the edge of display layers 28, such as to the edge light blocking structure to which metal plate 26 is grounded via conductive ink 34. Ink seal 36 may be formed from any desired ink, such as a conductive UV curable ink, a conductive ink that is cured in another manner, or other ink. Although FIG. 3B shows ink seal 36 extending from masking layer 32 to the edge light blocking structure at the edge of display layers 28, ink seal 36 may be applied directly to a portion of cover layer 30 and/or may be applied directly to other structures within device 10. In this way, the combination of conductive ink 34 and ink seal 36 may ensure that excessive charge does not accumulate on cover layer 30.

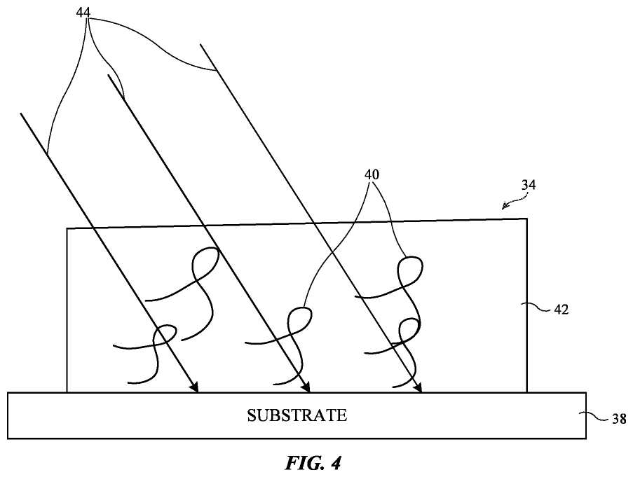

FIGS. 3A and 3B are merely illustrative embodiment of uses for a conductive ink, such as conductive ink 34. In general, conductive ink 34 may be used anywhere in an electronic device, such as electronic device 10, and/or a display, such as display 14. An example of conductive ink that may be used is shown in FIG. 4.

As shown in FIG. 4, a conductive ink, such as conductive ink 34, may include conductors, such as conductors 40, dispersed in a resin, such as resin 42. Conductive ink 34 may be applied on any desired structure or material, such as on substrate 38. Conductors 40 may be, in general, any desired conductor, and resin 42 may be any ultraviolet-curable resin. For example, resin 42 may be acrylic, epoxy, urethane, urethane acrylate, acrylic epoxies, acrylic polyesters, acrylic polyethers, silicones, acrylic polycarbonate, polyolefins, acrylic silicones, polyurethanes, polysiloxanes, or any other desired ultraviolet-curable resin.

To ensure that resin 42 can be fully cured using ultraviolet light at room temperature (e.g., without heating, moisture, or a secondary curing step), conductors 40 may have high aspect ratios. In other words, conductors 40 may have a high electrical conductivity, while having small thicknesses/diameters and/or small overall volumes. In this way, conductors 40 may provide sufficient conductivity, while taking up a small enough volume within resin 42 to allow ultraviolet light to pass through resin 42 unimpeded (or relatively unimpeded) and cure resin 42 fully.

Conductors 40 may be, as examples, silver nanowires, carbon nanotubes, conductive polymers, conductive pigment, graphene or other transparent conductor, or other conductive material. Embodiments in which conductors 40 are silver nanowires or carbon nanotubes may be described herein as illustrative examples, but any desired material may be used for conductors 40.

Conductors 40 may be 5% or less, 10% or less, or 15% or less of conductive ink 34 by weight. As shown in FIG. 4, the high aspect ratios and dispersed nature of conductors 40 may allow ultraviolet light 44 to pass through resin 42 unimpeded (or relatively unimpeded). In this way, ultraviolet light 44 may extend through resin 42 entirely and may fully cure resin 42.

In particular, ultraviolet light 44 may fully cure resin 42 at room temperature without heating or moisture. In some embodiments, ultraviolet light 44 may fully cure resin 42 in less than one minute, less than 30 seconds, less than 15 seconds, or other curing time, and resin 42 may have a thickness of at least 100 microns, at least 150 microns, at least 200 microns, or at least 500 microns, as examples. In other words, conductive ink 34 may have a curing depth of at least 100 microns, at least 150 microns, at least 200 microns, or at least 500 microns, and a curing time of less than one minute, less than 30 seconds, less than 15 seconds. However, these ranges are merely illustrative.

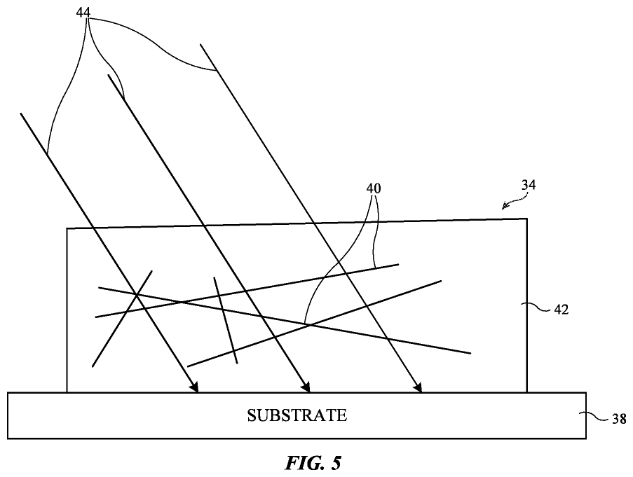

Although FIG. 4 shows conductors 40 as being curled back on each other (i.e., conductors 40 have a non-linear profile in FIG. 4), this is merely illustrative. In general, conductors 40 may have any desired shapes within resin 42. For example, as shown in FIG. 5, conductors 40 may have linear (or planar, if conductors 40 extend in a sheet with some width) profiles within resin 42. As shown in FIG. 5, due to the high aspect ratios of conductors 40, ultraviolet light 44 may pass through resin 42 fully, thereby curing resin 42 fully at room temperature without heating, moisture, or other curing techniques (as was the case with the conductors of FIG. 4). However, conductors 40 may be arranged in other shapes within resin 42, as desired.

In general, conductors 40 in conductive ink 34 may have some optical density (i.e., absorption) at visible wavelengths. For example, if carbon nanotubes are used in conductive ink 34, the ink may have an optical density of 0.1 or higher when at least 30 microns thick. However, it may be desirable to provide conductive ink with additional absorption properties. In particular, it may be desirable to create a conductive ink that is opaque (or translucent) at visible wavelengths, while being sufficiently transparent at ultraviolet wavelengths to allow the resin to cure.

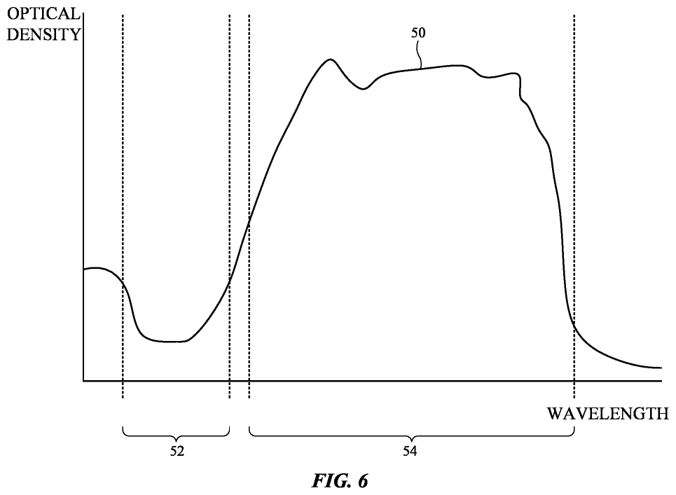

Conductive ink 34 may therefore be provided with pigment or dye (sometimes generally referred to as a colorant herein). For example, a pigment may be in resin 42 (i.e., may be mixed into resin 42 prior to curing) to increase the optical density of conductive ink 34. An illustrative graph showing the optical density of a conductive ink that has been provided with a pigment is shown in FIG. 6.

As shown in FIG. 6, an illustrative relationship between the wavelength and optical density for a conductive ink, such as conductive ink 34, that has been provided with pigment, is given by curve 50. Wavelengths 54 may be from 400 nm to 700 nm, or may correspond to all visible wavelengths, as examples. Across wavelengths 54, conductive ink 34 may have a high optical density, such as an optical density greater than 1.0, greater than 1.5, greater than 1.25, or other desired optical density (when conductive ink is 30 microns thick, for example). However, at wavelengths 52, which may correspond to ultraviolet wavelengths (or a portion of ultraviolet wavelengths, such as 300 nm to 375 nm), conductive ink 34 may have a low optical density, such as less than 1.0, less than 0.75, or less than 0.6, as examples. In this way, conductive ink 34 may be opaque or translucent across visible light wavelengths 54, while remaining transparent at ultraviolet wavelengths 52. Remaining transparent at ultraviolet wavelengths 52 may allow conductive ink 34 to cure using ultraviolet light.

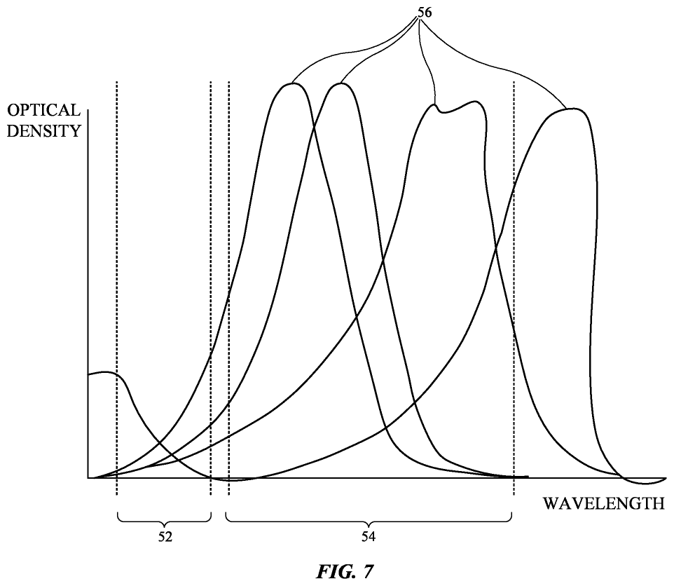

Instead of (or in addition to) adding pigment into the resin, conductive ink 34 may include dyes that absorb light of different wavelengths. An example of this arrangement is shown in FIG. 7. As shown in FIG. 7, each of curves 56 may correspond to an individual dye in conductive ink 34. Although each dye may have a different optical density (i.e., may absorb light of a different wavelength), the combined effect of all of the dyes may be to absorb light across visible wavelengths 54, while remaining transparent at ultraviolet wavelengths 52, similar to the optical density of the conductive ink with pigment in FIG. 6.

Although conductive ink 34 has been described as having a higher optical density when conductors 40 are carbon nanotubes, conductive ink 34 having any conductors 40 (such as silver nanowires) may include pigment or dyes to be transparent at ultraviolet wavelengths and opaque (or translucent) across visible wavelengths. By including pigment or dye that is transparent at ultraviolet wavelengths, conductive ink 34 may block visible light, while remaining curable using ultraviolet light.

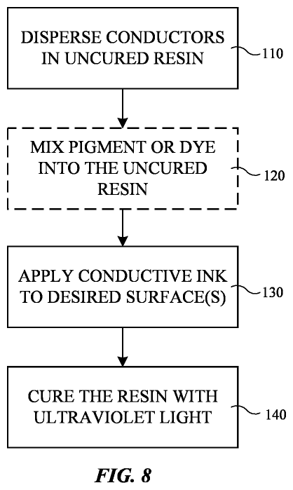

By incorporating pigment and/or dye into conductive ink 34, conductive ink 34 may be used as a coating in areas of electronic device 10 that are visible to a user. As an illustrative example, masking layer 32 may be omitted from FIG. 3A, and conductive ink 34 may serve to both ground metal plate 26 to cover layer 30 and to obscure underlying components from view by a user. As a result, any desired pigment and/or dye (such as pigment/dye of different colors, opacities, etc.) may be used in conductive ink 34 to give device 10 a desired appearance. If desired, however, masking layer 32 may be used in combination with pigment/dye in conductive ink 34. Regardless of whether pigment and/or dye is incorporated into conductive ink 34, a flowchart of illustrative steps used in forming and applying conductive ink to a desired surface is shown in FIG. 8.

As shown in FIG. 8, at step 110, conductors may be dispersed in an uncured resin. The conductors may have high aspect ratios and may be silver nanowires or carbon nanotubes, as examples. The uncured resin may be any desired resin that is curable with ultraviolet light, such as acrylic, epoxy, urethane, urethane acrylate, acrylic epoxies, acrylic polyesters, acrylic polyethers, silicones, acrylic polycarbonate, polyolefins, acrylic silicones, polyurethanes, or polysiloxanes. In some cases, it may be desirable for the conductors to be dispersed evenly throughout the uncured resin. In general, however, the conductors may be dispersed within the resin in any desired manner.

At optional step 120, pigment or dye may be mixed into the uncured resin. In general, any pigment or dye may be used. In some illustrative examples, pigment or dye that is opaque at visible wavelengths and transparent at ultraviolet wavelengths may be used in the uncured resin. For example, a single pigment that has a high optical density at visible wavelengths and a low optical density at ultraviolet wavelengths may be mixed into the uncured resin. Alternatively, multiple dyes, each with a different optical density, may be incorporated into the uncured resin. The multiple dyes may have a combined optical density that is high at visible wavelengths and low at ultraviolet wavelengths. In this way, the conductive ink may be opaque or translucent at visible wavelengths, while remaining transparent at ultraviolet wavelengths.

The pigment/dye may have any desired color. For example, the pigment/dye may impart a black color on the final conductive ink, but any desired color, such as blue or gray, may be used.

Although step 120 is shown as occurring after step 110, this is merely illustrative. In some embodiments, pigment or dye may be added to the uncured resin prior to the conductors.

At step 130, the conductive ink (which includes the conductors, uncured resin, and the optional pigment/dye) may be applied to a desired surface. For example, the conductive ink may be used to ground a cover layer in an electronic device to a metal structure within the electronic device, like in the embodiments of FIGS. 3A and 3B.

Although the conductive ink has been described as being used in an electronic device to ground a cover layer to an internal metal structure, this is merely illustrative. In general, conductive ink, such as conductive ink 34, may be used as a grounding structure, a conductive structure, or serve any other desired function either in or on an electronic device, or in another setting than an electronic device. Wherever the conductive ink is applied, the conductive ink may have a thickness of at least 100 microns, at least 150 microns, at least 200 microns, or at least 500 microns, as examples.

At step 140, the resin (and therefore the conductive ink) may be cured with ultraviolet light. For example, the conductive ink may be cured fully (i.e., through the whole thickness of the conductive ink) with ultraviolet light in less than one minute, less than 30 seconds, or less than 15 seconds, as examples. Moreover, the conductive ink may be cured using ultraviolet light without heat, moisture, or any additional curing step (although an additional step could be incorporated into the process if desired).

The foregoing is merely illustrative and various modifications can be made by those skilled in the art without departing from the scope and spirit of the described embodiments. The foregoing embodiments may be implemented individually or in any combination.

What is claimed is:

1. An ultraviolet-curable conductive ink, comprising:
an ultraviolet-curable resin; and
conductors dispersed in the ultraviolet-curable resin, wherein the ultraviolet-curable conductive ink has a curing depth of at least 100 microns in a curing time of less than one minute.

2. The ultraviolet-curable conductive ink defined in claim 1, wherein the conductors comprise a plurality of silver nanowires.

3. The ultraviolet-curable conductive ink defined in claim 2, wherein the plurality of silver nanowires are 10% or less of the weight of the ultraviolet-curable conductive ink.

4. The ultraviolet-curable conductive ink defined in claim 1, wherein the conductors comprise a plurality of carbon nanotubes.

5. The ultraviolet-curable conductive ink defined in claim 4, wherein the plurality of carbon nanotubes are 10% or less of the weight of the ultraviolet-curable conductive ink.

6. The ultraviolet-curable conductive ink defined in claim 1, wherein the ultraviolet-curable resin comprises a material selected from the group consisting of: acrylic, epoxy, urethane, urethane acrylate, acrylic epoxies, acrylic polyesters, acrylic polyethers, silicones, acrylic polycarbonate, polyolefins, acrylic silicones, polyurethanes, and polysiloxanes.

7. The ultraviolet-curable conductive ink defined in claim 1, wherein the ultraviolet-curable conductive ink has a curing depth of at least 200 microns in a curing time of less than thirty seconds.

8. The ultraviolet-curable conductive ink defined in claim 1, further comprising:
a pigment in the ultraviolet-curable resin.

9. The ultraviolet-curable conductive ink defined in claim 8, wherein the ultraviolet-curable conductive ink is opaque across visible wavelengths and transparent at ultraviolet wavelengths.

10. The ultraviolet-curable conductive ink defined in claim 1, further comprising:
dye in the ultraviolet-curable resin.

11. The ultraviolet-curable conductive ink defined in claim 10, wherein the dye in the ultraviolet-curable resin comprises multiple dyes and wherein the ultraviolet-curable conductive ink is opaque across visible wavelengths and transparent at ultraviolet wavelengths.

12. An electronic device, comprising:
a display comprising a display layer;
a transparent cover layer that overlaps the display; and
a conductive ink that extends from the display layer, wherein the conductive ink is ultraviolet-curable in less than one minute with a curing depth of at least 50 microns.

13. The electronic device defined in claim 12, further comprising:
an opaque masking layer on a portion of the transparent cover layer.

14. The electronic device defined in claim 13, wherein the conductive ink grounds the display layer to the opaque masking layer.

15. The electronic device defined in claim 13, wherein the display further comprises a metal plate and wherein the conductive ink grounds the metal plate to the display layer, the electronic device further comprising:
an ink seal layer that extends from the display layer to the opaque masking layer.

16. The electronic device defined in claim 12, wherein the conductive ink comprises silver nanowires or carbon nanotubes, comprises a colorant, and is opaque at visible wavelengths and transparent at ultraviolet wavelengths.

17. An electronic device, comprising:
a display comprising a display layer;
a cover layer that overlaps the display; and
an ultraviolet-curable conductive ink that extends from the display layer, wherein the ultraviolet-curable conductive ink comprises conductors selected from the group consisting of: silver nanowires and carbon nanotubes.

18. The electronic device defined in claim 17, wherein the ultraviolet-curable conductive ink has a thickness of at least 30 microns.

19. The electronic device defined in claim 18, wherein the ultraviolet-curable conductive ink further comprises a colorant selected from the group consisting of: pigment and dye, and wherein the ultraviolet-curable conductive ink is opaque across visible wavelengths and transparent at ultraviolet wavelengths.

20. The electronic device defined in claim 19, further comprising:
an opaque masking layer on a portion of the cover layer, wherein the ultraviolet-curable conductive ink grounds the opaque masking layer to the display layer.

21. The electronic device defined in claim 17, wherein the ultraviolet-curable conductive ink grounds the cover layer to the display layer.
